(19) United States
(12) Patent Application Publication
(10) Pub. No.: US 2025/0166167 A1
(43) Pub. Date: May 22, 2025

(54) SUBSTRATE PROCESSING SYSTEM, SUBSTRATE PROCESSING APPARATUS AND VISUALIZATION METHOD

(71) Applicant: Tokyo Electron Limited, Tokyo (JP)

(72) Inventor: Yusuke MIYAKUBO, Kumamoto (JP)

(21) Appl. No.: 18/953,435

(22) Filed: Nov. 20, 2024

(30) Foreign Application Priority Data
Nov. 20, 2023 (JP) 2023-196787
Sep. 17, 2024 (JP) 2024-159904

(51) Int. Cl. G06T 7/00; G03F 7/38; H01L 21/67; H01L 21/677; H04N 23/698

(52) U.S. Cl. CPC G06T 7/001; H01L 21/6715; H01L 21/67248; H01L 21/67769; H04N 23/698; G03F 7/38; G06T 2207/30148

(57) ABSTRACT

A substrate processing system includes: a substrate processing apparatus including a storage space where a substrate is accommodated; a camera directed toward the storage space; a pattern provided to extend within a field of view of the camera and configured to be captured by the camera through the storage space; and a map generation unit that generates map data indicating a fluid flow distribution in the storage space based on a change of an image of the pattern captured by the camera.

### CROSS-REFERENCE TO RELATED APPLICATIONS

This application is based on and claims priority from Japanese Patent Application Nos. 2023-196787 and 2024-159904, filed on Nov. 20, 2023 and Sep. 17, 2024, respectively, with the Japan Patent Office, the disclosures of which are incorporated herein in their entireties by reference.

### TECHNICAL FIELD

The present disclosure relates to a substrate processing system, a substrate processing apparatus, and a visualization method.

### BACKGROUND

Japanese Patent Application Laid-Open Publication No. H07-035764 discloses a method of visualizing an airflow, in which a tracer moving by the airflow is mixed into the airflow to be visualized, the airflow is irradiated with beam-like laser light having a wavelength of a specific visible light range in a repeatedly scanning manner, and the scattered light generated by the irradiation is allowed to pass through an optical filter having a relatively high transmittance only in the oscillation wavelength range of the laser light, and then the scattered light is recognized.

### SUMMARY

A substrate processing system according to an aspect of the present disclosure includes: a substrate processing apparatus having a storage space where a substrate is accommodated; a camera directed toward the storage space; a pattern that is provided to extend within a field of view of the camera and is configured to be captured by the camera through the storage space; and a map generation unit that generates map data indicating the fluid flow distribution in the storage space based on a change of an image of the pattern captured by the camera.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a plan view schematically illustrating the configuration of a wafer processing system.

FIG. 2 is a front view of the wafer processing system of FIG. 1.

FIG. 3 is a plan view illustrating a substrate processing apparatus.

FIG. 4 is a sectional view taken along the IV-IV line in FIG. 3.

FIG. 5 is a view illustrating a pattern.

FIGS. 6A and 6B are views illustrating a reference image and an evaluation image.

FIG. 7 is a plan view illustrating a modified example of the substrate processing apparatus.

FIG. 8 is a sectional view illustrating another modified example of the substrate processing apparatus.

FIG. 9 is a plan view illustrating yet another modified example of the substrate processing apparatus.

FIG. 10 is a plan view illustrating yet another modified example of the substrate processing apparatus.

FIG. 11 is a plan view illustrating yet another modified example of the substrate processing apparatus.

FIG. 12 is a plan view illustrating yet another modified example of the substrate processing apparatus.

FIG. 13 is a schematic diagram illustrating multiple components of the map data.

FIG. 14 is a block diagram illustrating a hardware configuration of an image processing apparatus.

FIG. 15 is a flow chart illustrating a visualization procedure.

FIG. 16 is a flow chart illustrating a modified example of the visualization procedure.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

Hereinafter, a wafer processing system as a substrate processing apparatus according to the present embodiment will be described with reference to drawings. In this specification, elements having substantially the same functional configurations are denoted by the same reference numerals and duplicate explanations thereof will be omitted.

### [Wafer Processing System]

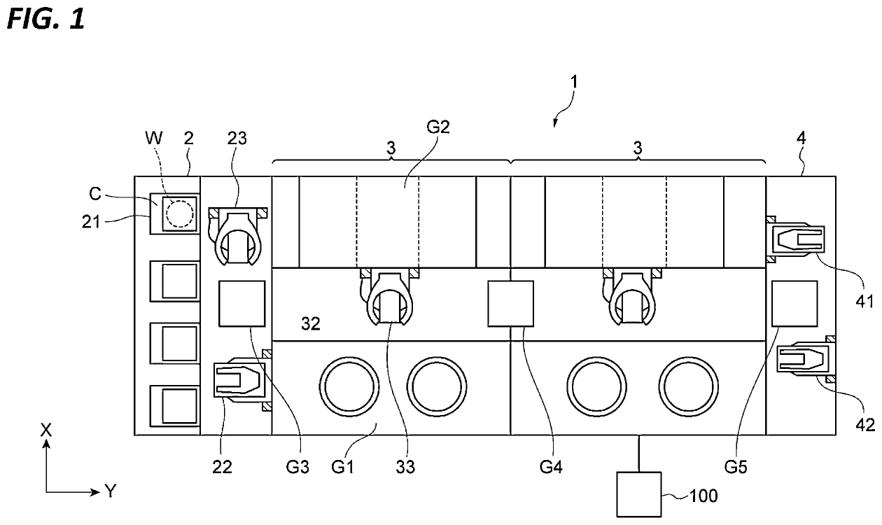

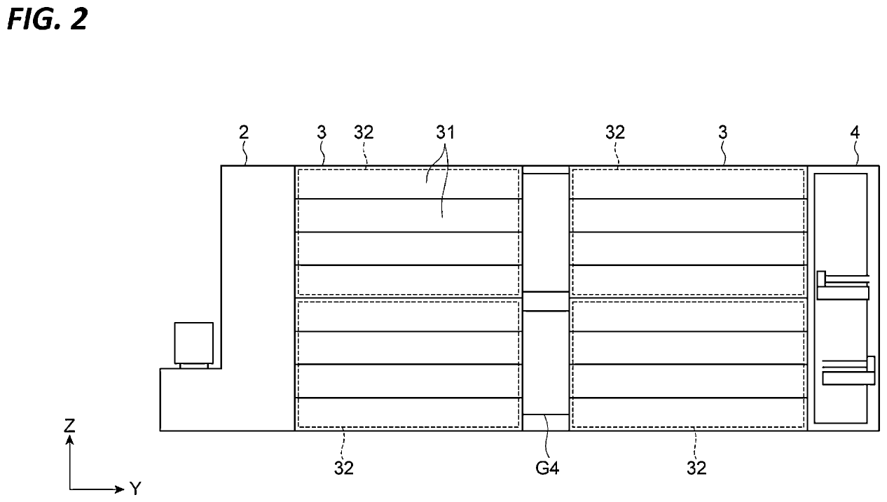

First, the configuration of a wafer processing system according to the present embodiment will be described. FIGS. 1 and 2 are a plan view and a front view schematically illustrating the outline of the configuration of a wafer processing system 1, respectively. In the present embodiment, a case where the wafer processing system 1 is a photolithography processing system that performs resist film forming processing and development processing on wafers W will be described as an example.

As illustrated in FIG. 1, the wafer processing system 1 includes a cassette station 2 to/from which a cassette C storing a plurality of wafers W is loaded/unloaded, and a processing station 3 provided with a plurality of various processing apparatuses for performing predetermined processing on the wafers W. Then, the wafer processing system 1 has a configuration where the cassette station 2, the processing station 3, and an interface station 4 are integrally connected. The interface station 4 allows wafers W to be transferred to/from an exposure device (not illustrated) adjacent thereto, on the opposite side of the processing station 3. As illustrated in FIG. 1, two processing stations 3 are installed between the cassette station 2 and the interface station 4 but one processing station 3 or three or more processing stations 3 may be installed.

The cassette station 2 is provided with a plurality of cassette stages 21 and wafer transfer devices 22 and 23. In the cassette station 2, a wafer W is conveyed by the wafer transfer device 22 or 23, between the cassette C placed on the stage 21 and the processing station 3. For this reason, each of the wafer transfer devices 22 and 23 is provided with driving mechanisms for directions such as the X direction, the Y direction, the vertical direction, and the direction around a vertical axis (0 direction) as necessary, and may be provided with driving mechanisms for all directions.

At least one of the wafer transfer devices 22 and 23 is capable of delivering wafers W to/from the cassettes C, and also is capable of performing a delivery operation of wafers W to/from the processing station 3. The delivery operation of wafers W to/from the processing station 3 is to perform the delivery of wafers W to/from, for example, a third block G3 provided with a delivery device accessible by a wafer transfer device 33 in the processing station 3 to be described below. The third block G3 may include a plurality of delivery devices (not illustrated) arranged and lined up in the vertical direction.

The cassette station 2 may include an inspection device (not illustrated) for inspecting wafers W, at a position accessible by either the wafer transfer device 22 or 23.

The processing station 3 is provided with a plurality of blocks, for example, three blocks of first, second, and fourth blocks G1, G2, and G4. Also, as illustrated in FIG. 2, layers 31 including the first and second blocks G1 and G2 are stacked in the vertical direction. For example, the first block G1 is provided on the front side of the processing station 3 (the negative side in the X direction in FIG. 1), and the second block G2 is provided on the rear side of the processing station 3 (the positive side in the X direction in FIG. 1). The fourth block G4 is provided on the interface station 4 side of the processing station 3 (the positive side in the Y direction in FIG. 1) or a connection portion with another adjacent processing station 3. The fourth block G4 may include a plurality of delivery devices arranged and lined up in the vertical direction. Also, the third block G3 may be provided within the processing station 3.

In the first block G1, a plurality of processing apparatuses, for example, a patterning film forming apparatus and a development processing apparatus, is disposed, but neither is illustrated. The patterning film forming apparatus may include, for example, not only a resist film forming apparatus, but also an anti-reflection film forming apparatus. For example, the processing apparatuses are arranged and lined up in the horizontal direction. The number, arrangement, or type of these processing apparatuses may be arbitrarily selected.

In the patterning film forming apparatus or the development processing apparatus, for example, a predetermined processing liquid or a predetermined gas is supplied onto a wafer W. In this manner, in the patterning film forming apparatus, a resist film is formed to be used as a mask when a film pattern on the lower layer side is formed or an anti-reflection film is formed to efficiently perform light irradiation processing such as, for example, exposure processing. Meanwhile, in the development processing apparatus, a part of the exposed resist film is removed to form an uneven shape as the mask.

For example, in the second block G2, heat treatment devices (not illustrated) for performing heat treatment such as heating or cooling of wafers W are provided and lined up in the vertical direction and the horizontal direction. Also, in the second block G2, a hydrophobic treatment device that performs a hydrophobic treatment to improve the fixability between a resist liquid and a wafer W and a periphery exposure device that exposes the peripheral portion of a wafer W are provided and lined up in the vertical direction (the Z direction in FIG. 2) and the horizontal direction, but neither is illustrated. The number or arrangement of the heat treatment device, the hydrophobic treatment device, and the periphery exposure device may also be arbitrarily selected.

As illustrated in FIG. 1, in a plan view, a wafer transfer area 32 is formed in a region interposed between the first block G1 and the second block G2. For example, the wafer transfer device 33 is disposed in the wafer transfer area 32.

The wafer transfer device 33 has, for example, a transfer arm that is freely movable in the X direction, the Y direction, the θ direction and the vertical direction. The wafer transfer device 33 may move within the wafer transfer area 32 and transfer wafers W to predetermined devices within the surrounding first, second, third, and fourth blocks G1, G2, G3, and G4. When there is a plurality of processing stations 3 as in FIG. 1, the wafer transfer device 33 provided in the processing station 3 located on the interface station 4 side may transfer wafers W to predetermined devices within a fifth block G5 to be described below as well as the first, second, and fourth blocks G1, G2, and G4.

For example, the wafer transfer devices 33 are vertically arranged. One wafer transfer device 33 may transfer wafers W to predetermined devices located at the height of upper layers 31 among the vertically stacked layers 31 (see, e.g., FIG. 2). To predetermined devices located at the height of layers 31 located below these upper layers 31, another wafer transfer device 33 may transfer wafers W. A plurality of wafer transfer areas 32 is provided to enable such conveyance of wafers W. Also, the wafer transfer device 33 may be provided for each layer 31. The number of wafer transfer devices 33 or the number of layers 31 corresponding to one wafer transfer device 33 may be arbitrarily selected.

Also, a shuttle conveyance device (not illustrated) may be present in the wafer transfer area 32, the first block G1 or the second block G2. The shuttle conveyance device linearly conveys wafers W between a space adjacent to one side of the processing station 3 and another space adjacent to the opposite side.

The interface station 4 includes the fifth block G5 provided with a plurality of delivery devices, and wafer transfer devices 41 and 42. In the interface station 4, the wafer transfer device 41 or 42 is used to transfer wafers W between the exposure device and the fifth block G5 to which the wafers W are delivered by the wafer transfer device 33. Thus, each of the wafer transfer devices 41 and 42 is provided with driving mechanisms for directions such as the X direction, the Y direction, the vertical direction, and the direction around a vertical axis (θ direction) as necessary, and may be provided with driving mechanisms for all directions. At least one of the wafer transfer devices 41 and 42 may support a wafer W and transfer the wafer W between the delivery device within the fifth block G5 and the exposure device.

A cleaning device for cleaning the surface of a wafer W or the above-described periphery exposure device may be provided within the interface station 4, at a position accessible by either of the wafer transfer device 41 or 42.

As described above, the inspection device may be provided in the cassette station 2, but may also be provided in each of the processing station 3 and the interface station 4, at a location accessible by any of the transfer arms (33, 41, and 42 in FIG. 1 or FIG. 2) provided inside the station.

The wafer processing system 1 is provided with a control device 100. The control device 100 is, for example, a computer, and has a program storage (not illustrated). The program storage stores a program for controlling the processing of the wafer W in the wafer processing system 1. The program storage also stores a program for controlling the operation of a drive system of the above-described various processing devices or the transfer devices so as to realize wafer processing in the wafer processing system 1. The program may be recorded in a computer-readable storage medium H and may be installed from the storage medium H to the control device 100.

### [Operation of Wafer Processing System]

The wafer processing system 1 is configured as described above. Next, descriptions will be made on an example of wafer processing performed using the wafer processing system 1 configured as described above.

First, the cassette C storing a plurality of wafers W is carried into the cassette station 2 of the wafer processing system 1 and is placed on the cassette stage 21. Then, the wafers W are sequentially taken out of the cassette C by the wafer transfer device 22 or 23, and are transferred to the delivery device of the third block G3.

The wafer W transferred to the delivery device of the third block G3 is supported by the wafer transfer device 33 and is transferred to the hydrophobic treatment device provided in the second block G2, and then is subjected to a hydrophobic treatment. Next, the wafer W is transferred to the resist film forming apparatus by the wafer transfer device 33, and a resist film is formed on the wafer W. Then, the wafer W is transferred to the heat treatment device and is pre-baked, and then is transferred to the delivery device of the fifth block G5. As in FIGS. 1 and 2, when the plurality of processing stations 3 is present, before being transferred to the delivery device of the fifth block G5, the wafer W is once placed on the delivery device of the fourth block G4, and then is delivered between the wafer transfer devices 33. Also, as necessary, the wafer W may be transferred to the periphery exposure device by the wafer transfer device 33 and the periphery of the wafer W may be subjected to exposure processing.

The wafer W transferred to the delivery device of the fifth block G5 is transferred to the exposure device by the wafer transfer devices 41 and 42, and is subjected to exposure processing by a predetermined pattern. Before the exposure processing, the cleaning device may clean the wafer W.

The wafer W that has been subjected to the exposure processing is transferred to the delivery device of the fifth block G5 by the wafer transfer devices 41 and 42. After that, the wafer W is transferred to the heat treatment device by the wafer transfer device 33 and is subjected to post-exposure baking.

The wafer W that has been subjected to the post-exposure baking is transferred to the development processing apparatus by the wafer transfer device 33, and then is developed. After the development is completed, the wafer W is transferred to the heat treatment device 40 by the wafer transfer device 33 and is subjected to post-baking processing.

Thereafter, the wafer W is transferred to the delivery device of the third block G3 by the wafer transfer device 33, and is transferred to the cassette C of the predetermined cassette stage 21 by the wafer transfer device 22 or 23 of the cassette station 2. In this manner, a series of photolithography steps is completed.

The wafer processing system in the present disclosure is not limited to the above-described configuration and operation. For example, in the above embodiment, descriptions have been made on a case where the wafer W is delivered between the interface station 4 and the exposure device, but there may be no direct connection with the exposure device. In such a case, for example, the wafer W is transferred from the cassette station 2 to the processing station 3 and is subjected to required processing, and then is transferred again to the cassette station 2 so as to be taken out. Also, among those exemplified as the processing devices, any device that is not required may not be provided, or the processing in that device may not be performed.

### [Substrate Processing Apparatus]

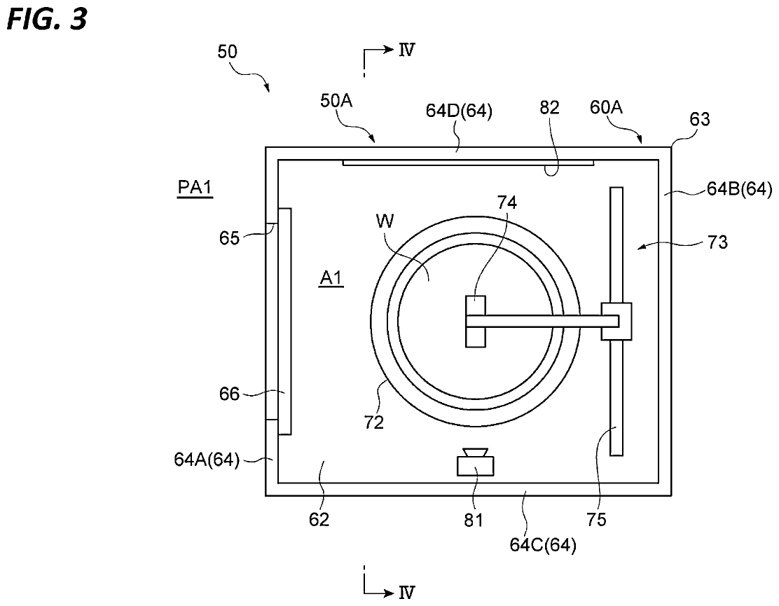

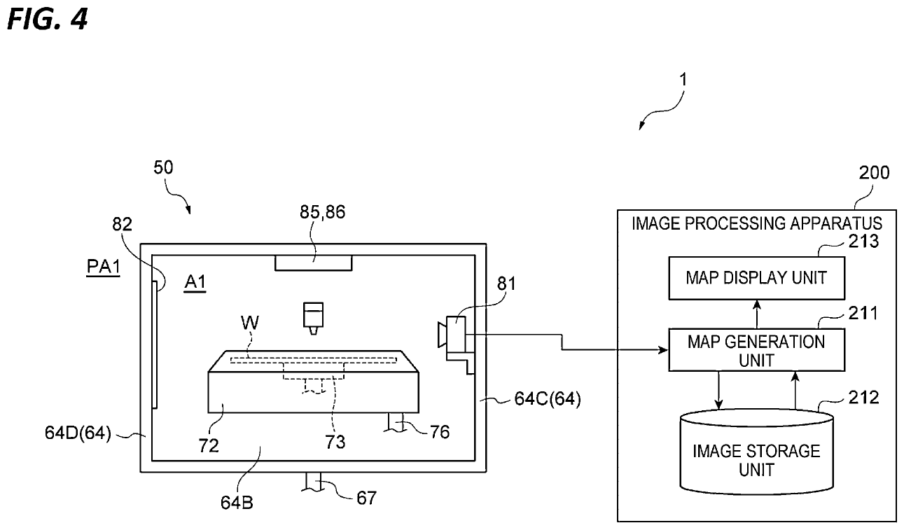

FIG. 3 is a plan view illustrating a substrate processing apparatus 50, and FIG. 4 is a sectional view taken along the IV-IV line in FIG. 3. The substrate processing apparatus 50 is included in the wafer processing system 1. For example, the substrate processing apparatus 50 includes the patterning film forming apparatus 50A.

The patterning film forming apparatus 50A includes a chamber 60A, a rotary holder 71, a cup 72, and a liquid supply 73. The chamber 60A has a storage space A1 where a wafer W (a semiconductor wafer: an example of a substrate) is accommodated. For example, the chamber 60A includes a top plate 61, a bottom plate 62, a peripheral wall 63, a shutter 66, and an exhaust port 67. The top plate 61 extends horizontally above the storage space A1. The bottom plate 62 extends horizontally below the storage space A1. The peripheral wall 63 surrounds the storage space A1 between the top plate 61 and the bottom plate 62 and connects the top plate 61 to the bottom plate 62.

The peripheral wall 63 includes a partition wall 64 that separates the storage space A1 from a peripheral space PAL. For example, the peripheral wall 63 includes a pair of partition walls 64A and 64B and a pair of partition walls 64C and 64D. The partition walls 64A and 64B face each other with the storage space A1 being interposed therebetween. The paired partition walls 64C and 64D face each other with the storage space A1 being interposed therebetween in a direction intersecting (for example, perpendicular to) the direction in which the storage space A1 is interposed between the partition walls 64A and 64B.

An opening 65 is formed in the partition wall 64. Through the opening 65, the wafer W passes when carried into the storage space A1 from the peripheral space PA1 and carried out of the storage space A1 and to the peripheral space PAL. For example, the opening 65 is formed in the partition wall 64A. The shutter 66 is driven by, for example, an electric motor, etc., and is moved up and down so as to open and close the opening 65.

The exhaust port 67 is opened in the storage space A1, and sends the gas (an example of a fluid) in the storage space A1, to the outside of the chamber 60A. This ventilates the storage space A1, and then, for example, vaporized matter generated through the processing on the wafer W is discharged to the outside of the chamber 60A.

The rotary holder 71 supports and sucks the horizontally disposed wafer W from below, and is rotated around the vertical axis by being driven by an electric motor, etc. The liquid supply 73 supplies a processing liquid to the wafer W accommodated in the storage space A1. The processing liquid may be, for example, a film forming liquid, etc. for forming a film for patterning. The film forming liquid may be, for example, a resist liquid containing a negative or positive resist material.

For example, the liquid supply 73 includes a nozzle 74 and a nozzle transport device 75. The nozzle 74 is opened downwards and is disposed above the rotary holder 71, and ejects the processing liquid toward the wafer W held by the rotary holder 71. The nozzle transport device 75 is driven by an electric motor, etc. and moves the nozzle 74 along the horizontal direction. The nozzle transport device 75 may be configured not only to move the nozzle 74 in the horizontal direction but also to raise and lower the nozzle 74.

The cup 72 is opened upwards and accommodates the wafer W held by the rotary holder 71. The cup 72 collects the processing liquid shaken off the wafer W by, for example, the rotation of the rotary holder 71 and the wafer W. The cup 72 has an exhaust port 76. The exhaust port 76 is opened in the cup 72, and sends the gas in the cup 72 to the outside of the cup 72. This ventilates the inside of the cup 72, and then, for example, vaporized matter generated through the processing on the wafer W is discharged to the outside of the cup 72. For example, the exhaust port 76 is opened at the bottom of the cup 72.

Due to the exhaust port 67 and the exhaust port 76, a gas flow (an example of a fluid flow) is formed in the storage space A1. For example, when the gas in the storage space A1 is sent out of the chamber 60A via the exhaust port 67, a gas flow is formed in the storage space A1, in which the gas enters the storage space A1 through the opening 65, and exits the chamber 60A through the exhaust port 67. When the gas in the cup 72 is sent out of the cup 72 via the exhaust port 76, a gas flow is formed in the storage space A1, in which the gas enters the cup 72 from above, and exits the cup 72 through the exhaust port 76. The fluid flow occurring in the storage space A1 may affect the processing of the wafer W. For example, the gas flow in the storage space A1 of the patterning film forming apparatus 50A may affect, for example, the film thickness uniformity of the patterning film formed on the wafer W.

In order to control the influence of the fluid flow, it is necessary to visualize the distribution of the fluid flow. Therefore, the substrate processing apparatus 50 further includes a camera 81 and a pattern 82. The camera 81 is directed toward the storage space A1 in the chamber 60A.

The camera 81 includes, for example, an image sensor such as a charge coupled device (CCD) or a complementary metal-oxide-semiconductor (CMOS), and an optical system that forms an image from light in a visual field direction, on the image sensor. The image sensor includes plurality of pixels arranged in a matrix shape.

The pattern 82 is formed so as to extend at least within the field of view of the camera 81, and is captured by the camera 81 via the storage space A1. The pattern 82 changes the image to be captured by the camera 81 due to the Schlieren effect. For example, the pattern 82 changes the image to be captured by the camera 81, according to a change in the refractive index of the fluid in the storage space A1.

For example, when the refractive index of the fluid in the storage space A1 is changed, the position of light entering the camera 81 from the pattern 82 is changed. This may cause a partial change in, for example, the shape of the pattern 82 to be captured by the camera 81. If the pattern 82 does not exist, for example, a change in the shape of the pattern 82 does not occur in the image to be captured by the camera 81. For this reason, when the pattern 82 exists, it can be thought that the change of the image caused by a change of the refractive index of the fluid in the storage space A1 occurs due to the pattern 82.

The refractive index of the fluid correlates with the density of the fluid. Since the density of the fluid changes with the flow of the fluid, the refractive index of the fluid in the storage space A1 also correlates with the flow of the fluid in the storage space A1. For example, in a place where the fluid flow exists in the storage space A1 (hereinafter, referred to as a “flow portion”), the refractive index of the fluid changes due to the fluid flow. Meanwhile, in a place where the fluid flow does not exist in the storage space A1 (hereinafter, referred to as a “stationary portion”), the refractive index of the fluid is not changed. For this reason, for the portion of the pattern 82 from which light enters the camera 81 via the stationary portion, the image formation position is not changed whereas for the portion of the pattern 82 from which light enters the camera 81 via the flow portion, the image formation position is changed. Accordingly, in the image captured by the camera 81, the distribution of the fluid flow in the storage space A1 is visualized as a partial fluctuation in the shape of the pattern 82. In this manner, image fluctuations occurring by the fluid flow due to the Schlieren effect are made clear by the pattern 82. Thus, the fluid flow distribution in the storage space A1 may be clearly visualized.

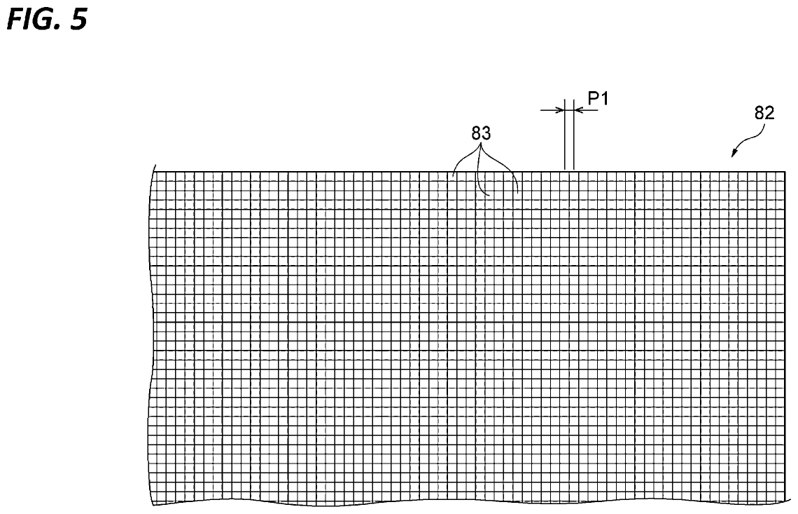

As illustrated in FIG. 5, the pattern 82 may include a plurality of motifs 83 arranged to be dispersed in the field of view of the camera 81. The plurality of motifs 83 further clarifies image fluctuations caused by the Schlieren effect. Therefore, it is possible to more clearly visualize the distribution of the fluid flow in the substrate processing apparatus 50.

For example, the motifs 83 are arranged two-dimensionally. An example of a two-dimensional arrangement may be a matrix-shape arrangement in which the motifs are arranged and lined up in mutually perpendicular row and column directions, but is not limited to this. For example, the motifs 83 may be arranged in a staggered lattice shape or a honeycomb shape.

The motif 83 is a constituent unit of the pattern 82. The shape and size of the motif 83 are not particularly limited. For example, the motif 83 may be circular or rectangular, or may be a polygon such as a hexagon. The plurality of motifs 83 may include two or more motifs 83 that differ from each other in at least one of the shape, size and color. The motifs 83 may be identical in the shape, size and color. The motifs 83 may be in contact with each other, or may be separated from each other.

The motifs 83 may be arranged at a constant pitch, or may be arranged at a non-constant pitch. The pitch is, for example, the center-to-center distance. For example, when the motifs 83 are arranged in a matrix shape, the pitches of the motifs 83 may be constant in the row direction, and the pitches of the motifs 83 may be constant in the column direction.

The motifs 83 and gaps between the motifs 83 may be distinguished by different colors. For example, the motifs 83 may be white, and the gaps between the motifs 83 may be black. Conversely, the motifs 83 may be black, and the gaps between the motifs 83 may be white.

In the pattern 82 illustrated in FIG. 5, the motifs 83 having the same shape, size and color are arranged and lined up in a matrix shape at a constant pitch P1. Each of the motifs 83 is rectangular, and the motifs 83 are separated from each other by lattice-like lines 84. The motifs 83 and the lines 84 between the motifs 83 are distinguished by different colors. For example, the motifs 83 are white, and the lines 84 are black.

The pattern 82 may be formed by the unevenness on the surface. For example, the motifs 83 may be recessed portions and gaps between the motifs 83 may be raised portions, so that the motifs 83 and the gaps between the motifs 83 may be distinguished by the light and shade formed by the unevenness. Conversely, the motifs 83 may be raised portions and gaps between the motifs 83 may be recessed portions, so that the motifs 83 and the gaps between the motifs 83 may be distinguished. The pattern 82 may be formed by a combination of the surface unevenness and the color.

Referring back to FIG. 4, the pattern 82 may be formed on the partition wall 64 that separates the storage space A1 from the peripheral space PA1. A wide pattern may be formed by using the partition wall, and then map data related to a wide range may be generated. The formation of the pattern 82 on the partition wall 64 includes both forming the pattern 82 by performing painting, processing, etc. on the partition wall 64 itself and attaching, for example, a panel formed with the pattern 82 to the partition wall 64.

For example, the pattern 82 is formed on the partition wall 64C or the partition wall 64D adjacent to the partition wall 64A in which the opening 65 is formed. In FIG. 4, the pattern 82 is formed on the partition wall 64D, and the partition wall 64C is provided with the camera 81 facing the pattern 82 through the storage space A1, but the present disclosure is not limited thereto. The pattern 82 may be formed on the partition wall 64C, and the camera 81 may be provided on the partition wall 64D.

The wafer processing system 1 may further include an image processing apparatus 200. The image processing apparatus 200 generates map data indicating the distribution of the fluid flow in the storage space A1 based on the change of the image of the pattern 82 captured by the camera 81. The fluid flow distribution is, for example, a relationship between the position in the storage space A1 (the position in the image captured by the camera 81), and the state of the fluid flow (for example, at least one of a flow velocity, a flow rate, and a flow direction). The fluid flow distribution may be a relationship between the position in the storage space A1 and the density of the fluid.

Image fluctuations occurring by the fluid flow due to the Schlieren effect may be converted into data, so that, for example, filtering processing or emphasizing processing is enabled. This is effective in more clearly visualizing the fluid flow distribution.

For example, the image processing apparatus 200 has a map generation unit 211 and an image storage unit 212 as functional components (hereinafter, referred to as “functional blocks”).

The map generation unit 211 generates map data indicating the fluid flow distribution in the storage space A1, based on the change of the image of the pattern 82 captured by the camera 81. The map generation unit 211 may generate map data based on a difference between a reference image and an evaluation image of the storage space A1 captured by the camera 81. At a time when the evaluation image is captured by the camera 81, the fluid flow distribution is different from that at a time when the reference image is captured. The change of the image of the pattern 82 is made clear based on the difference between the reference image and the evaluation image. Accordingly, map data that more clearly indicates the fluid flow distribution in the storage space A1 is generated.

For example, the map generation unit 211 acquires a reference image from the camera 81 at a predetermined first time, and stores the reference image in the image storage unit 212. Next, the map generation unit 211 acquires an evaluation image from the camera 81 at a predetermined second time, and calculates a difference between the reference image stored in the image storage unit 212 and the evaluation image. For example, the map generation unit 211 calculates the difference between the reference image and the evaluation image, for each pixel of the camera 81. For example, the map generation unit 211 calculates a difference between a pixel value in the reference image and a pixel value in the evaluation image, for each pixel. It is possible to generate high-definition map data in which the flow distribution is expressed pixel by pixel. The pixel value is, for example, a numerical value indicating brightness. For example, the map generation unit 211 generates matrix data indicating a difference between the pixel value in the reference image and the pixel value in the evaluation image, as map data, for each pixel of the camera 81.

The first time is previously determined as, for example, a period during which no fluid flow is occurring in the storage space A1 or the fluid flow in the storage space A1 is very small. The first time may be previously determined as a period during which no flow directed toward the wafer W is occurring in the fluid in the storage space A1 or the fluid flow directed toward the wafer W is very small in the storage space A1. As an example, the first time may be determined as a period during which exhaust from the exhaust port 67 is performed and exhaust from the exhaust port 76 is not performed.

The second time is previously determined as a period during which the fluid flow in the storage space A1 is larger (for example, the flow velocity is high) than that during the period determined as the first time. The second time is previously determined as a period during which the fluid flow directed toward the wafer W is larger (for example, the flow velocity is high) in the storage space A1 than that during the period determined as the first time. As an example, the second time may be determined as a period during which exhaust from the exhaust port 76 is performed and the processing liquid is supplied to the wafer W.

As described above, when the second time (the acquisition timing of the evaluation image) is determined as a period during which the processing liquid is supplied to the wafer W, the map generation unit 211 generates map data indicating the flow distribution of the fluid (gas) in a state where the processing liquid is adhering to the wafer W. The map data generated in a state where the processing liquid is adhering to the wafer W is useful for analyzing the effect of the gas in the storage space A1, on the processing liquid.

Also, since vaporized matter generated from the processing liquid may change the refractive index of the gas, a difference in the refractive index, between a portion where the vaporized matter is removed by the fluid and a portion where the vaporized matter remains, is large. Therefore, the change in the refractive index caused by the flow becomes larger due to the difference in the vaporized matter content, and thus image fluctuations caused by the Schlieren effect may be further clarified.

The camera 81 may repeatedly photograph the evaluation image. The map generation unit 211 may generate map data whenever the evaluation image is captured by the camera 81. When the generation of map data is repeated, the reference image is repeatedly used. When the reference image is repeatedly used, due to, for example, an unexpected positional shift of the camera 81, there is a possibility that a difference occurs between conditions that should be the same when the reference image is captured and when the evaluation image is captured. When such a difference between conditions occurs, it is impossible to distinguish whether the difference between the evaluation image and the reference image is caused by the difference between conditions or is caused by the flow distribution. Thus, there is also a possibility that it will be difficult to grasp the flow distribution based on the map data.

Therefore, the map generation unit 211 may update the reference image based on a plurality of evaluation images obtained when the camera 81 repeatedly photographs the evaluation image, and may generate map data based on a difference between the updated reference image, and an evaluation image captured after the update of the reference image. Even when, for example, the unexpected positional shift occurs in the camera 81, the above-described difference between conditions is kept low due to the update of the reference image. Therefore, it is possible to continue the generation of map data that makes it easy to grasp the flow distribution.

For example, whenever map data is generated based on the difference between a reference image and an evaluation image, the map generation unit 211 may update the reference image based on the used evaluation image (that has been used for generation of the map data). For example, the map generation unit 211 may generate the weighted average of the reference image and the evaluation image, as a new reference image. The weight of each of the reference image and the evaluation image is determined in advance by a preliminary experiment, etc.

The image processing apparatus 200 may further include a map display unit 213 as a functional block. The map display unit 213 displays a map image indicating the fluid flow distribution in the storage space A1 based on the map data, on, for example, a display device (e.g., a display device of a user interface 296 to be described below). For example, the map display unit 213 generates display data by performing emphasizing processing, filtering processing, etc. on the map data, and displays the map image based on the display data. For example, the map display unit 213 displays a map image in which the state of the flow is expressed in colors, for each portion in the image of the pattern 82.

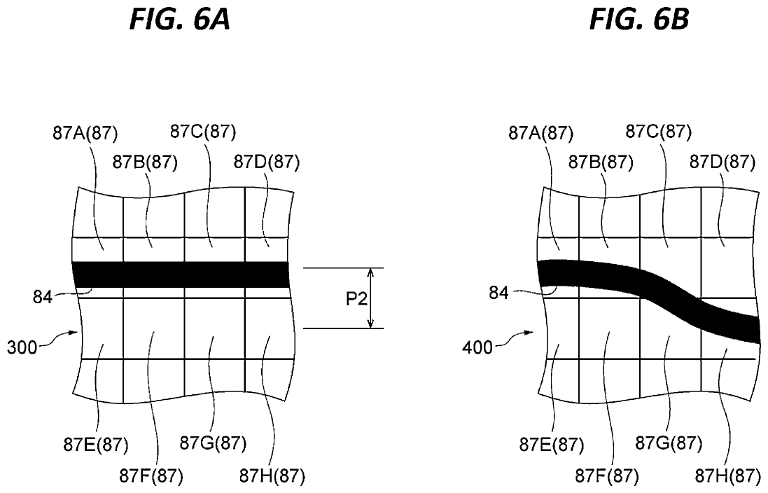

FIGS. 6A and 6B are views illustrating a part of a reference image and a part of an evaluation image in an enlarged scale, respectively. FIG. 6A is a reference image, and FIG. 6B is an evaluation image. As illustrated in FIGS. 6A and 6B, the camera 81 has a plurality of pixels 87. The pixels 87 are arranged in a matrix shape at a pitch P2. The array pitch (the pitch P1) of the motifs 83 in the image of the pattern 82 may be larger than the array pitch (pitch P2) of the pixels 87.

In a reference image 300 of FIG. 6A, the image of the line 84 between the motifs 83 is formed on pixels 87A, 87B, 87C, and 87D, and is not formed on pixels 87E, 87F, 87G, and 87H. In an evaluation image 400 of FIG. 6B, the image formation position of the line 84 has changed from that in the reference image 300 due to the Schlieren effect. For example, the image portion, which has been formed on the pixel 87C in the reference image 300, straddles both the pixels 87C and 87G in the evaluation image 400. Also, the image portion, which has been formed on the pixel 87D in the reference image 300, has completely moved to the pixel 87H. In this example, at least in the pixels 87C and 87D and the pixels 87G and 87H, a difference between the pixel value in the reference image 300 and the pixel value in the evaluation image 400 becomes large. This indicates that the flow of the fluid is occurring in the passage region of the image portion formed on at least the pixels 87C and 87D and the pixels 87G and 87H.

Referring back to FIG. 4, the substrate processing apparatus 50 may further include a temperature controller 85. By the temperature controller 85, the temperature of the fluid in the storage space A1 at the time when the evaluation image is captured (e.g., the second time) is made different from that at the time when the reference image is captured (e.g., the first time). For example, the temperature controller 85 heats or cools the fluid upstream of the fluid flow occurring in the storage space A1. For example, when the exhaust port 76 is opened in the cup 72 at the lower portion of the cup 72, the top side of the cup 72 may be the upstream of the fluid flow. In this case, the temperature controller 85 may heat or cool the fluid above the cup 72.

When the fluid is heated or cooled upstream of the flow, the heated or cooled fluid flows into the portion where the flow is occurring, and a temperature difference from the portion where the flow is not occurring becomes large. For this reason, a difference in the refractive index between the portion where the flow is occurring and the portion where the flow is not occurring is enlarged due to the temperature difference. In this manner, the change in the refractive index caused by the flow becomes large due to the temperature difference, and thus image fluctuations caused by the Schlieren effect may be further clarified.

The temperature controller 85 may have a thermoelectric element provided in the flow path of the fluid, and may be configured to supply electric power to the thermoelectric element so as to change the temperature of the fluid. The thermoelectric element is an element that heats or cools the surroundings by supplying of electric power. For example, the thermoelectric element may be a Peltier element, etc. The temperature controller 85 may be easily turned ON/OFF.

The temperature controller 85 only needs to be disposed so as to heat or cool at least the fluid flowing within the map data generation range, and may not necessarily be disposed above the cup 72. The temperature controller 85 may be disposed within the field of view of the camera 81.

The substrate processing apparatus 50 may further include an additive unit 86 instead of or in addition to the temperature controller 85. The additive unit 86 supplies an additive that changes the refractive index, to the fluid in the storage space A1, at the time when the evaluation image is captured (e.g., the second time). For example, the additive may be vaporized matter of organic solvent (e.g., vaporized matter of acetone), etc. For example, the additive unit 86 supplies an additive to the fluid upstream of the fluid flow occurring in the storage space A1. For example, the additive unit 86 supplies the additive to the fluid above the cup 72.

When the additive is supplied to the fluid upstream of the flow, the fluid containing the additive flows into the portion where the flow is occurring, and a difference in the additive content from the portion where the flow is not occurring becomes large. For this reason, a difference in the refractive index between the portion where the flow is occurring and the portion where the flow is not occurring is enlarged due to the difference of the additive content. In this manner, the change in the refractive index caused by the flow becomes large due to the difference of the additive content, and thus image fluctuations caused by the Schlieren effect may be further clarified.

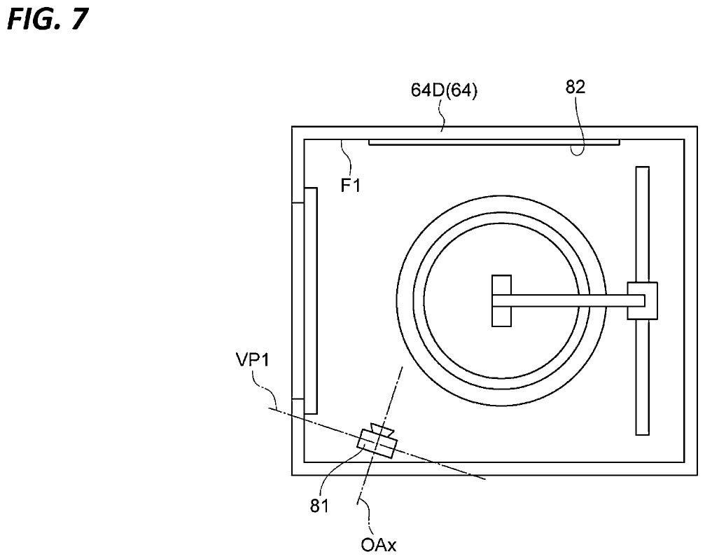

FIG. 7 is a plan view illustrating a modified example of the substrate processing apparatus. As illustrated in FIG. 7, the pattern 82 may be formed on a surface F1 inclined with respect to a plane VP1 perpendicular to an optical axis OAx of the camera 81. For example, the optical axis Oax of the camera 81 may be inclined with respect to the normal of the inner surface of the partition wall 64D on which the pattern 82 is formed.

Even when the motifs 83 are uniform and are arranged at a constant pitch, the sizes may be made different between the motifs 83 in the image of the pattern 82. By making the sizes of the motifs 83 different in the image of the pattern 82, image fluctuations caused by the Schlieren effect may be further clarified.

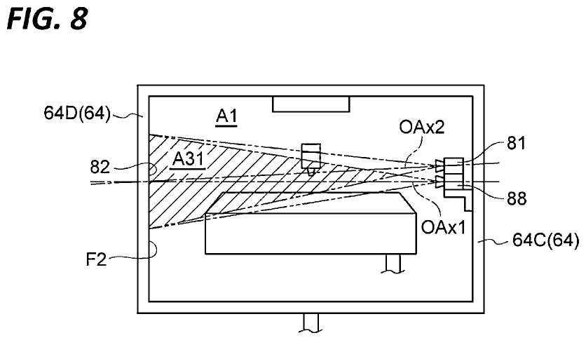

FIG. 8 is a sectional view illustrating another modified example of the substrate processing apparatus. As illustrated in FIG. 8, the substrate processing apparatus 50 may include a projection device 88 instead of the pattern 82. The projection device 88 projects the pattern 82 onto a surface F2 for projection. The surface F2 is provided to extend within the field of view of the camera 81, and is formed to be captured by the camera 81 via the storage space A1. For example, when the camera 81 is provided on the partition wall 64C, the surface F2 is formed on the inner surface of the partition wall 64D. The projection device 88 may be configured to project the pattern 82 onto the surface F2 via the storage space A1. For example, the projection device 88 is provided on the partition wall 64C and projects the pattern 82 onto the surface F2 of the partition wall 64D via the storage space A1. Instead of providing the pattern 82, providing the projection device 88 that projects the pattern 82 onto the surface F2 prepared for projection is also included in providing the pattern 82.

According to the projection device 88, the pattern 82 may be more easily formed than the permanently installed pattern 82. Also, it is possible to suppress the deterioration of the pattern 82, which is caused by the processing liquid, etc.

The projection device 88 may project the pattern 82 onto the surface F2 through a space A31 between the camera 81 and a region of the surface F2 onto which the pattern 82 is projected. The light emitted from the projection device 88 is refracted twice when passing through the space A31 toward the surface F2, and when passing through the space A31 toward the camera 81. Accordingly, compared to when the camera 81 photographs the pattern 82 fixed on the surface F2, the change of the pixel value caused by refraction becomes large. Thus, it is possible to generate map data that indicates the flow distribution with higher sensitivity.

For example, the projection device 88 may project the pattern 82 onto the surface F2 via the space within the range of the field of view of the camera 81. The projection device 88 may be disposed such that light directed toward the surface F2 from the projection device 88, and light directed toward the camera 81 from the surface F2 pass through the common space A31. An angle formed by an optical axis Oax1 that is the central axis of light emitted from the projection device 88, and an optical axis Oax2 that is the central axis of light entering the camera 81 may be 300 or less, 200 or less, or 100 or less.

The camera 81 may be fixed to the projection device 88. The fixation of the camera 81 to the projection device 88 means that the projection device 88 holds the camera 81, thereby fixing the position of the camera 81. For example, in FIG. 8, the camera 81 is disposed on the projection device 88 fixed to the partition wall 64C, and the camera 81 is held by the projection device 88. Since the relative vibration of the camera 81 with respect to the pattern 82 is suppressed, image fluctuations caused by the Schlieren effect may be further clarified.

The surface F2 may have a color tone or a texture that makes the pattern 82 projected by the projection device 88 clearer. The surface F2 may be formed by attaching a sheet to, for example, the partition wall 64D, or may be formed by performing painting or processing on the partition wall 64D itself.

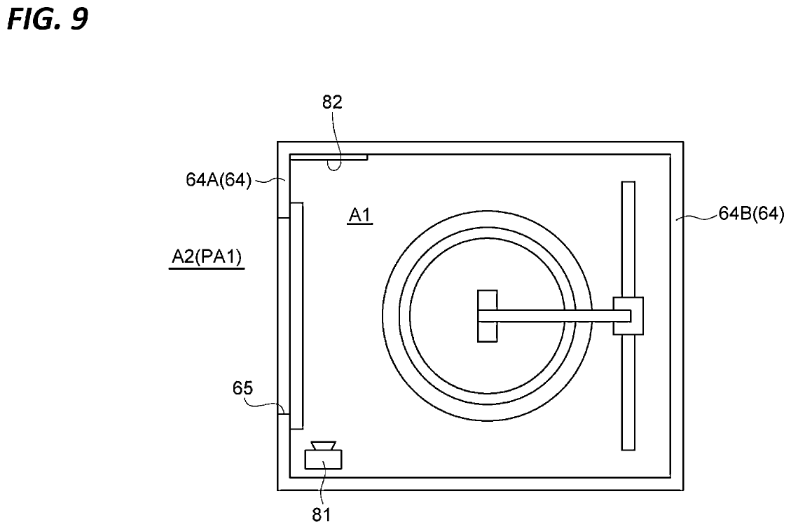

The arrangement of the camera 81 and the pattern 82 is not limited to the above-exemplified arrangement, and may be changed in any way as long as the pattern 82 may be imaged by the camera 81 through the storage space A1. FIG. 9 illustrates a modified example of the arrangement of the camera 81 and the pattern 82 in FIG. 3. In FIG. 9, a storage space A2 is a portion of the peripheral space PA1 that is connected to the storage space A1 through the opening 65. The storage space A2 accommodates the wafer W before loading into the storage space A1 and after unloading from the storage space A1.

In FIG. 9, the camera 81 and the pattern 82 are disposed with the opening 65 being interposed therebetween, near the opening 65 in the storage space A1. For example, the camera 81 and the pattern 82 are disposed near the partition wall 64A in which the opening 65 is formed, between the partition wall 64A and the partition wall 64B. According to such arrangement, it is possible to easily visualize the distribution of the fluid flowing from the storage space A2 (a second storage space) to the storage space A1 via the opening 65, and the distribution of the fluid flowing from the storage space A1 to the storage space A2 (the second storage space) via the opening 65.

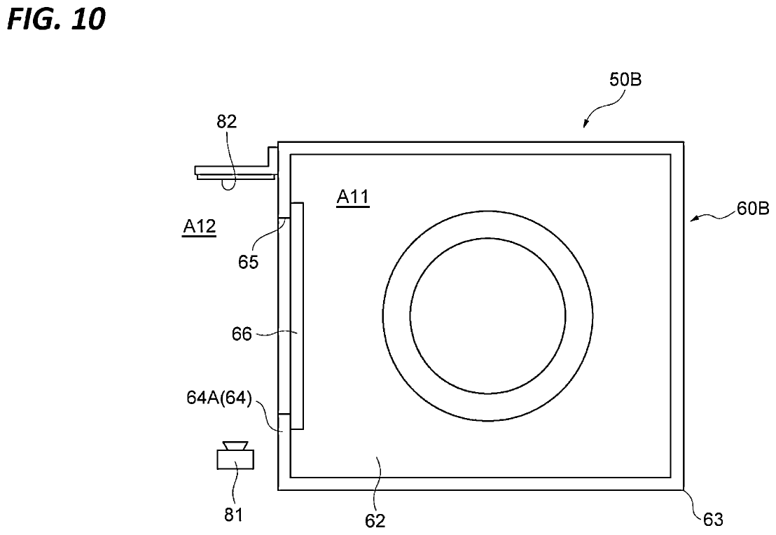

The above example is about a case where the camera 81 and the pattern 82 are provided in the patterning film forming apparatus 50A, but the processing apparatus in which the camera 81 and the pattern 82 are provided is not limited to the patterning film forming apparatus 50A. FIG. 10 is a plan view illustrating a case where the camera 81 and the pattern 82 are provided in the heat treatment device. The substrate processing apparatus 50 illustrated in FIG. 10 includes a heat treatment device 50B.

The heat treatment device 50B includes a chamber 60B and a heat plate 77. The chamber 60B includes a storage space A11 in which the wafer W is accommodated. Like the chamber 60A, the chamber 60B includes the top plate 61, the bottom plate 62, the peripheral wall 63, the shutter 66, and the exhaust port 67. The opening 65 is formed in the partition wall 64 of the peripheral wall 63. The substrate processing apparatus 50 includes a storage space A12 connected to the storage space A11 via the opening 65. The heat plate 77 supports the wafer W in the storage space A11, and heats the wafer W with a heater.

In FIG. 10, the camera 81 and the pattern 82 are disposed with the opening 65 being interposed therebetween, near the opening 65 in the storage space A12. The map generation unit 211 may generate map data indicating the fluid flow distribution around the opening 65 in a state where the temperature of the fluid in the storage space A12 and the temperature of the fluid in the storage space A11 (the second storage space) are different. For example, the map generation unit 211 acquires a reference image in a state where the shutter 66 has closed the opening 65. Since the storage space A11 is heated by the heat plate 77 in a state where the opening 65 is closed by the shutter 66, the temperature of the fluid differs between the storage space A11 and the storage space A12. In this state, after the shutter 66 opens the opening 65, the map generation unit 211 acquires an evaluation image, and generates map data based on a difference between the reference image and the evaluation image.

In the storage space A12, the fluid heated by the heat plate 77 flows into the portion where the flow from the opening 65 is occurring, and a temperature difference from the portion where the flow is not occurring becomes large. For this reason, a difference in the refractive index between the portion where the flow is occurring and the portion where the flow is not occurring is enlarged due to the temperature difference. This further clarifies image fluctuations caused by the Schlieren effect, and it is possible to clearly visualize the fluid flow between the storage space A11 and the storage space A12. In this configuration, it can be said that the heat plate 77 also functions as the temperature controller 85.

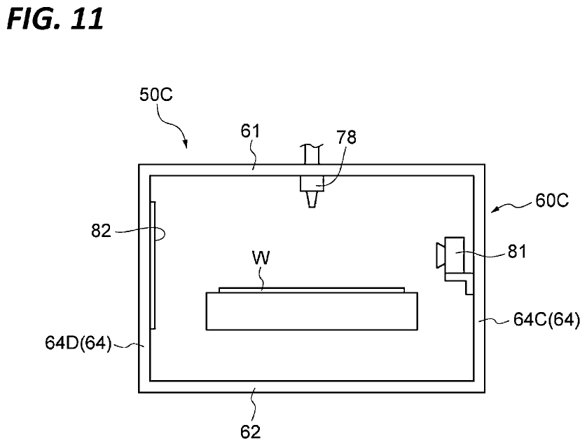

The substrate processing apparatus 50 may be included in another substrate processing system different from the wafer processing system 1. For example, the substrate processing apparatus 50 illustrated in FIG. 11 includes a gas processing apparatus 50C of another substrate processing system. The gas processing apparatus 50C is an apparatus that supplies a processing gas such as, for example, an etching gas to the wafer W.

The gas processing apparatus 50C has a chamber 60C and a gas supply 78. The chamber 60C has a storage space A21 where a wafer W is accommodated. Like the chamber 60A, the chamber 60C includes the top plate 61, the bottom plate 62, and the peripheral wall 63.

The gas supply 78 supplies a processing gas from above toward the wafer W that is accommodated in the storage space A21 and is horizontally held. In FIG. 11, the camera 81 and the pattern 82 are provided on the partition walls 64C and 64D facing each other in the partition wall 64 of the peripheral wall 63, respectively. The map generation unit 211 generates map data indicating the flow distribution of the processing gas, as the fluid flow distribution. For example, the map generation unit 211 acquires a reference image in a state where the processing gas is not being supplied from the gas supply 78. After the supply of the processing gas from the gas supply 78 is started, the map generation unit 211 acquires an evaluation image, and generates map data based on a difference between the reference image and the evaluation image.

According to the substrate processing apparatus 50 of FIG. 11, it is possible to generate map data useful for analyzing the supply state of the processing gas to the wafer W. In the storage space A21, the processing gas flows into the portion where the flow from the gas supply 78 is occurring, and the amount of the processing gas is larger than that in the portion where the flow is not occurring. Thus, a difference in the refractive index between the portion where the flow is occurring and the portion where the flow is not occurring is enlarged according to the amount of the processing gas. This further clarifies image fluctuations caused by the Schlieren effect, and it is possible to clearly visualize the flow of the processing gas. In this configuration, it can be said that the gas supply 78 also functions as the additive unit 86.

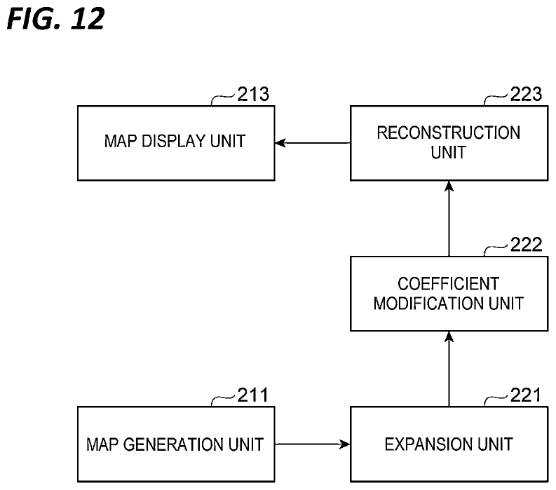

The image processing apparatus 200 may be configured to use a two-dimensional orthogonal polynomial so as to perform at least one of filtering processing and emphasizing processing on map data. For example, as illustrated in FIG. 12, the image processing apparatus 200 may further include an expansion unit 221, a coefficient modification unit 222, and a reconstruction unit 223 as functional blocks. The expansion unit 221 expands map data into a series of multiple components each of which is expressed by a two-dimensional orthogonal polynomial. For example, each of the components is matrix data in which the number of rows and the number of columns equal to those in the map data. The series means data obtained by adding up the components with weights. The weight (coefficient) of each of the components is determined such that the addition result matches the map data.

The coefficient modification unit 222 modifies the coefficient of at least one modification target component among the components in the series. For example, for the purpose of filtering processing, among the components, at least one component to be reduced through filtering processing is at least one modification target component. The coefficient modification unit reduces the coefficient of at least one modification target component. For the purpose of emphasizing processing, among the components, at least one component to be increased through emphasizing processing is at least one modification target component. The coefficient modification unit increases the coefficient of at least one modification target component.

The reconstruction unit 223 reconstructs the map data based on the series in which the coefficient of at least one modification target component is modified. For example, the reconstruction unit 223 reconstructs map data by adding up the components with weights.

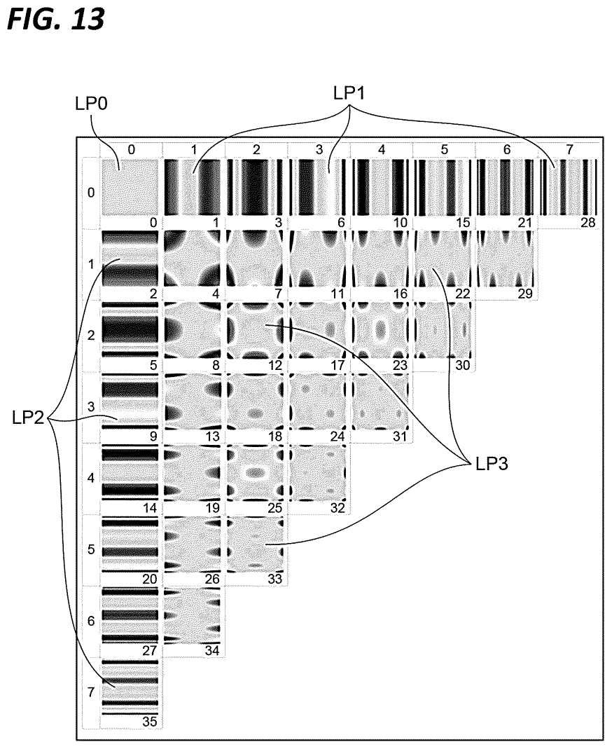

The two-dimensional orthogonal polynomial is a two-dimensional Legendre polynomial. FIG. 13 is a schematic view illustrating multiple components each of which is a two-dimensional Legendre polynomial. The components include a component LP0 that does not form a pattern, a plurality of components LP1 forming a vertical stripe pattern, a plurality of components LP2 forming a horizontal stripe pattern, and a plurality of components LP3 as a combination of a vertical stripe pattern and a horizontal stripe pattern.

When, for example, the fluid flow is likely to occur along the vertical direction, the coefficient modification unit 222 may set at least one of the components LP1 as at least one modification target component, and may increase the coefficient of at least one modification target component. This makes it easier to emphasize the fluid flow distribution. Also, the coefficient modification unit 222 may set at least one of the components LP2 as at least one modification target component, and may reduce the coefficient of at least one modification target component. This reduces horizontal stripe patterns having little relation to the fluid flow, thereby making it easier to grasp the fluid flow distribution.

The two-dimensional orthogonal polynomial is not necessarily limited to the two-dimensional Legendre polynomial. The two-dimensional orthogonal polynomial may be, for example, a two-dimensional Chebyshev polynomial.

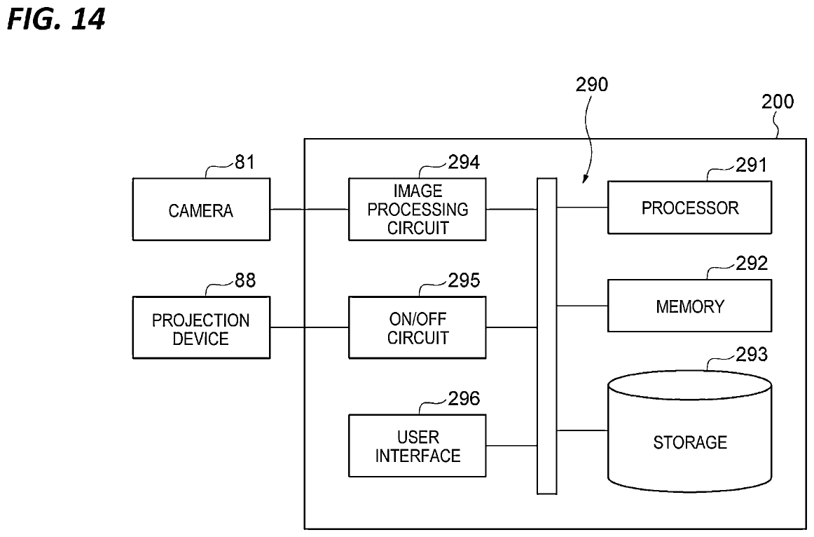

FIG. 14 is a block diagram illustrating a hardware configuration of the image processing apparatus 200. As illustrated in FIG. 14, the image processing apparatus 200 has a circuit 290. The circuit 290 has a processor 291, a memory 292, a storage 293, an image processing circuit 294, an ON/OFF circuit 295, and the user interface 296.

The storage 293 includes, for example, at least one non-volatile storage medium. Examples of the non-volatile storage medium may include a hard disk drive, a solid-state drive, and a flash memory. The non-volatile storage medium may include a portable storage medium such as an optical disc. The storage 293 stores a program for causing the image processing apparatus 200 to execute the generation of map data indicating the fluid flow distribution based on the change of the image of the pattern 82 captured by the camera 81. For example, the storage 293 stores a program for allowing each of the functional blocks to be configured in the image processing apparatus 200.

The memory 292 includes at least one volatile storage medium. For example, the volatile storage medium may be a random access memory. The memory 292 temporarily stores a program loaded from the storage 293. The processor 291 includes one or more arithmetic devices. For example, the arithmetic device may be a central processing unit (CPU) or a graphics processing unit (GPU). The processor 291 executes the program loaded in the memory 292 so that each of the functional blocks may be configured in the image processing apparatus 200. The processor 291 may temporarily store the arithmetic result in the memory 292.

The image processing circuit 294 causes the camera 81 to take a photograph in response to a request from the processor 291, and acquires the captured image from the camera 81. The ON/OFF circuit 295 causes the projection device 88 to start or stop the projection of the pattern 82 in response to a request from the processor 291. The user interface 296 includes at least one input device and at least one display device. For example, the input device may be a keyboard or a mouse. For example, the display device may be a liquid crystal monitor. The input device may be incorporated into the display device so as to constitute a touch panel. In response to a request from the processor 291, regarding the input to one or more input devices, the user interface 296 outputs and displays, for example, text, and images, on one or more display devices.

The image processing apparatus 200 may be incorporated into the control device 100, or may be incorporated into hardware separate from the control device 100. A network line such as a WAN or a LAN may be interposed between the image processing apparatus 200 and the substrate processing apparatus 50.

### [Visualization Procedure]

As an example of a visualization method, a visualization procedure executed by the image processing apparatus 200 is exemplified. This procedure includes: acquiring an image of the pattern 82 captured by the camera 81 through the storage space A1, the pattern 82 being formed to extend within the field of view of the camera 81 facing the storage space A1; and generating map data indicating the fluid flow distribution in the storage space A1 based on a change of the acquired image.

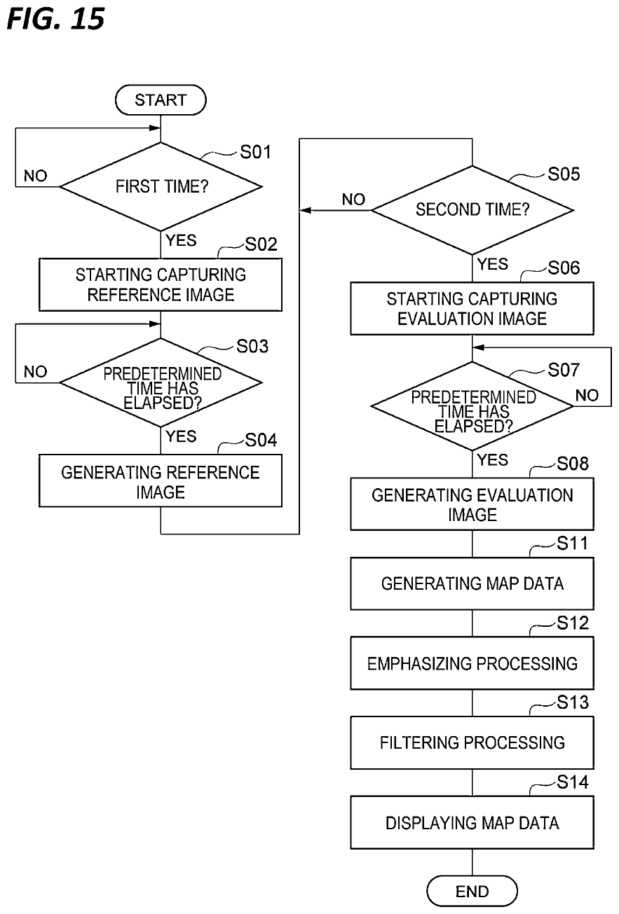

FIG. 15 is a flow chart illustrating a visualization procedure. As illustrated in FIG. 15, first, the image processing apparatus 200 executes steps S01, S02, S03, and S04. In step S01, the map generation unit 211 waits for the first time. In step S02, the map generation unit 211 causes the camera 81 to start taking a video so as to generate a reference image. In step S03, the map generation unit 211 waits for the lapse of a predetermined time. In step S04, the map generation unit 211 generates a reference image based on a plurality of still images constituting the video captured by the camera 81. For example, the map generation unit 211 generates a reference image by performing, for example, an averaging process on the plurality of still images, and stores the reference image in the image storage unit 212. In this manner, the reference image is acquired.

Next, the image processing apparatus 200 executes steps S05, S06, S07, and S08. In step S05, the map generation unit 211 waits for the above second time. In step S06, the map generation unit 211 causes the camera 81 to start taking a video so as to generate an evaluation image. In step S07, the map generation unit 211 waits for the lapse of a predetermined time. In step S08, the map generation unit 211 generates an evaluation image based on a plurality of still images constituting the video captured by the camera 81. For example, the map generation unit 211 generates an evaluation image by performing, for example, an averaging process on the plurality of still images, and stores the evaluation image in the image storage unit 212.

Next, the image processing apparatus 200 executes steps S11, S12, S13, and S14. In step S11, the map generation unit 211 generates map data based on a difference between the reference image and the evaluation image. In step S12, the map generation unit 211 performs emphasizing processing on the map data. The emphasizing processing is processing of enlarging, for example, a difference in the pixel value between pixels. In step S13, the map generation unit 211 performs filtering processing on the map data. The filtering processing is processing of removing a value caused by noise, from the pixel value. The execution order of the emphasizing processing and the filtering processing is not limited to this, and the emphasizing processing may be executed after the filtering processing.

In step S14, the map display unit 213 displays a map image based on the map data obtained after the emphasizing processing and the filtering processing. Here, the visualization procedure is completed.

When the image processing apparatus 200 includes the expansion unit 221, the coefficient modification unit 222, and the reconstruction unit 223, steps S12 and S13 may be executed by the expansion unit 221, the coefficient modification unit 222, and the reconstruction unit 223 as described above.

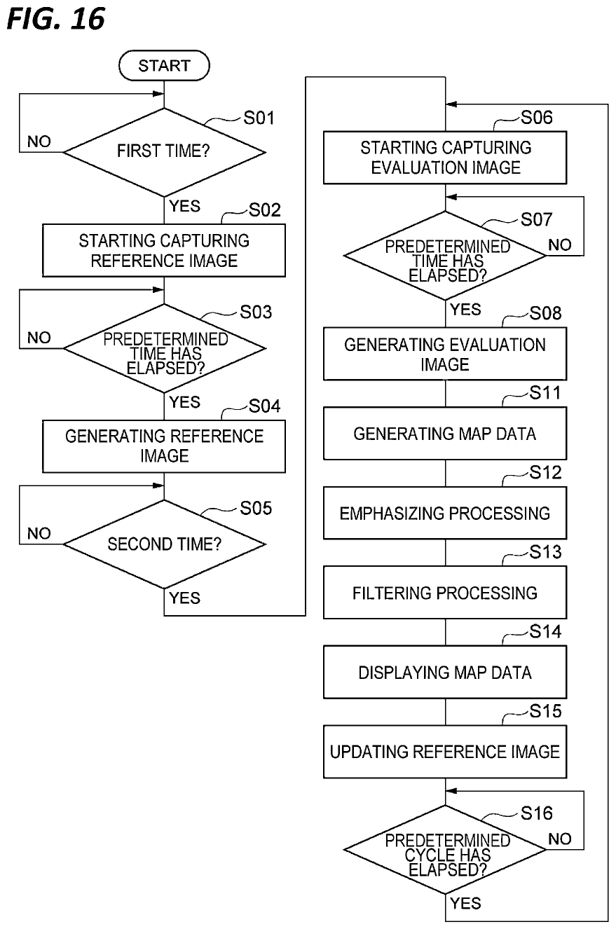

FIG. 16 is a flow chart illustrating a modified example of the visualization procedure, and is different from the flow chart in FIG. 15 in that evaluation image generation and map data generation are repeated. In the flow chart of FIG. 16, steps S01 to S14 are the same as steps S01 to S14 in the flow chart of FIG. 15.

In the flow chart of FIG. 16, the image processing apparatus 200 executes step S15 after the map image is displayed in step S14. In step S15, the map generation unit 211 updates the reference image. For example, the map generation unit generates the weighted average of the evaluation image generated in step S08 and the reference image, as a new reference image, and stores the new reference image in the image storage unit 212.

Then, the image processing apparatus 200 executes step S16. In step S16, the map generation unit 211 waits for the lapse of a predetermined cycle from the point in time of start of step S06. Next, the image processing apparatus 200 returns the process to step S06. Accordingly, the generation of the evaluation image, the generation of the map data, the display of the map image, and the update of the reference image are repeatedly executed at the above predetermined cycle.

### SUMMARY

The above-exemplified embodiments include the following configurations.

(1) A substrate processing system 1 including: a substrate processing apparatus 50 having a storage space A1 where a substrate W is accommodated; a camera 81 directed toward the storage space A1; a pattern 82 that is provided to extend within a field of view of the camera 81 and is configured to be captured by the camera 81 through the storage space A1; and a map generation unit 211 that generates map data indicating a fluid flow distribution in the storage space A1 based on a change of an image of the pattern 82 captured by the camera 81.

Image fluctuations occurring by the fluid flow due to the Schlieren effect are made clear by the pattern 82. Thus, map data that clearly indicates the fluid flow distribution in the storage space A1 is generated. Therefore, it is possible to easily visualize the fluid flow distribution in the substrate processing apparatus 50.

(2) The substrate processing system 1 described in (1), in which the map generation unit 211 generates map data based on a difference between a reference image 300 of the storage space A1 captured by the camera 81 and an evaluation image 400 captured by the camera 81 at a timing when the fluid flow distribution is different from a timing when the reference image 300 is captured.

The change of the image of the pattern 82 is made clear based on the difference between the reference image 300 and the evaluation image 400. Accordingly, map data that more clearly indicates the fluid flow distribution in the storage space A1 is generated. Therefore, it is possible to more clearly visualize the fluid flow distribution in the substrate processing apparatus 50.

(3) The substrate processing system 1 described in (2), in which the camera 81 has a plurality of pixels 87, and the map generation unit 211 generates the map data based on a difference between the value of the pixel 87 in the evaluation image 400 and the value of the pixel 87 in the reference image 300, for each of the pixels 87.

It is possible to generate high-definition map data.

(4) The substrate processing system 1 described in any one of (1) to (3), in which the pattern 82 includes a plurality of motifs 83 arranged to be dispersed in the field of view of the camera 81.

The plurality of motifs 83 further clarifies image fluctuations caused by the Schlieren effect. Thus, it is possible to more clearly visualize the fluid flow distribution in the substrate processing apparatus 50.

(5) The substrate processing system 1 described in (4), in which the camera 81 has a plurality of pixels 87, and an array pitch of the plurality of motifs 83 in the image of the pattern 82 is larger than the array pitch of the plurality of pixels 87.

It is possible to suppress occurrence of moire.

(6) The substrate processing system 1 described in (4) or (5), in which the pattern 82 includes the plurality of motifs 83 that are uniform and are arranged at a constant pitch, and is provided on a surface inclined with respect to a plane perpendicular to an optical axis of the camera 81.

By making the sizes of the motifs 83 different in the image of the pattern 82, image fluctuations caused by the Schlieren effect may be further clarified.

(7) The substrate processing system 1 described in any one of (1) to (6), in which the pattern 82 is provided on a partition wall that separates the storage space A1 from a peripheral space PA1.

A wide pattern 82 may be formed by using the partition wall, and then map data related to a wide range may be generated.

(8) The substrate processing system 1 described in any one of (1) to (7) further includes a projection device 88 that is provided to extend within the field of view of the camera 81, and projects the pattern 82 onto a surface that is captured by the camera 81 via the storage space A1.

It is possible to easily form the pattern 82. Also, it is possible to suppress the deterioration of the pattern 82, which is caused by the processing liquid, etc.

(9) The substrate processing system 1 described in (8), in which the projection device 88 projects the pattern 82 onto the surface through a space A31 between the camera 81 and a region of the surface onto which the pattern 82 is projected.

The light emitted from the projection device 88 is refracted twice when passing through the space A31 toward the surface, and when passing through the space A31 toward the camera 81. Accordingly, compared to when the camera 81 photographs the pattern 82 fixed on the surface, the change of the pixel value caused by refraction becomes large. Thus, it is possible to generate map data that indicates the flow distribution with higher sensitivity.

(10) The substrate processing system 1 described in (8), in which the camera 81 is fixed to the projection device 88.

Since the relative vibration of the camera 81 with respect to the pattern 82 is suppressed, image fluctuations caused by the Schlieren effect may be further clarified.

(11) The substrate processing system 1 described in (2) or (3) further includes a temperature controller 85 that makes a temperature of the fluid in the storage space A1 at a timing when the evaluation image 400 is captured to be different from a temperature of the fluid at a timing when the reference image 300 is captured.

The change in the refractive index caused by the flow becomes large, and thus image fluctuations caused by the Schlieren effect may be further clarified.

(12) The substrate processing system 1 described in (11), in which the temperature controller 85 has a thermoelectric element provided in the flow path of the fluid, and supplies electric power to the thermoelectric element, thereby changing the temperature of the fluid.

The temperature controller 85 may be easily turned ON/OFF.

(13) The substrate processing system 1 described in (2) or (3) further includes an additive unit 86 that supplies an additive that changes a refractive index, to the fluid in the storage space A1, at the timing when the evaluation image 400 is captured.

The change in the refractive index caused by the flow becomes large, and thus image fluctuations caused by the Schlieren effect may be further clarified.

(14) The substrate processing system 1 described in (2) or (3), in which the camera 81 repeatedly photographs the evaluation image, and the map generation unit 211 generates the map data whenever the evaluation image is captured by the camera 81.

It is possible to continuously monitor the fluid distribution.

(15) The substrate processing system 1 described in (14), in which the map generation unit 211 updates the reference image based on a plurality of evaluation images obtained by repeatedly capturing the evaluation image with the camera 81, and generates the map data based on a difference between the updated reference image, and an evaluation image captured after the reference image is updated.

When the reference image is repeatedly used, due to, for example, an unexpected positional shift of the camera 81, there is a possibility that a difference occurs between conditions that should be the same when the reference image is captured and when the evaluation image is captured. When such a difference between conditions occurs, it is impossible to distinguish whether the difference between the evaluation image and the reference image is caused by the difference between conditions or is caused by the flow distribution. Thus, there is also a possibility that it will be difficult to grasp the flow distribution based on the map data. Meanwhile, even when, for example, the unexpected positional shift occurs in the camera 81, the above-described difference between conditions is kept low due to the update of the reference image. Therefore, it is possible to continue the generation of map data that makes it easy to grasp the flow distribution.

(16) The substrate processing system 1 described in any one of (1) to (15) further includes: an expansion unit 221 that expands the map data into a series of a plurality of components each of which is expressed by a two-dimensional orthogonal polynomial; a coefficient modification unit 222 that modifies the coefficient of at least one modification target component among the plurality of components in the series; and a reconstruction unit that reconstructs the map data based on the series in which the coefficient of the at least one modification target component is modified.

It is possible to easily perform filtering processing of removing components that make it difficult to grasp the fluid flow distribution and emphasizing processing for emphasizing the fluid flow distribution.

(17) The substrate processing system 1 described in (16), in which the two-dimensional orthogonal polynomial is a two-dimensional Legendre polynomial.

It is possible to more easily perform filtering processing and emphasizing processing.

(18) The substrate processing system 1 described in any one of (1) to (17), the map generation unit 211 generates the map data indicating a gas flow distribution as the fluid flow distribution.

It is possible to easily visualize the gas flow distribution.

(19) The substrate processing system 1 described in (18), in which the substrate processing apparatus 50 further includes a liquid supply 73 that supplies a processing liquid to the substrate W accommodated in the storage space A1, and the map generation unit 211 generates the map data indicating the gas flow distribution in a state where the processing liquid adheres to the substrate W.

It is possible to generate map data useful for analyzing the effect of the gas in the storage space A1, on the processing liquid.

(20) The substrate processing system 1 described in any one of (1) to (19), in which the substrate processing apparatus 50 further includes a second storage space A11 connected to the storage space A12 via an opening 65, and the map generation unit 211 generates the map data indicating the fluid flow distribution around the opening 65 in a state where a temperature of the fluid in the storage space A12 and a temperature of the fluid in the second storage space A11 are different.

It is possible to easily visualize the fluid flow between the storage space A12 and the second storage space A11.

(21) The substrate processing system 1 described in any one of (1) to (20), in which the substrate processing apparatus 50 further includes a gas supply 78 that supplies the processing gas to the substrate W accommodated in the storage space A1, and the map generation unit 211 generates the map data indicating the flow distribution of the processing gas, as the fluid flow distribution.

It is possible to generate map data useful for analyzing the supply state of the processing gas to the substrate W.

(22) A substrate processing apparatus 50 including: a storage space A1 where a substrate W is accommodated; a camera 81 directed toward the storage space A1; and a pattern 82 that is provided to extend within the field of view of the camera 81, and is captured by the camera 81 via the storage space A1, and configured to change the image to be captured by the camera 81, according to a change in refractive index of the fluid in the storage space A1.

(23) A method of visualizing a fluid flow distribution in a storage space A1 of a substrate processing apparatus 50 where a substrate W is accommodated, the method including: acquiring an image of a pattern 82 provided to extend within a field of view of the camera 81 and configure to be captured by a camera 81 through the storage space A1, the camera 81 being directed toward the storage space A1; and generating map data indicating the fluid flow distribution in the storage space A1 based on a change of the acquired image.

According to the present disclosure, it is possible to provide a system in which the fluid flow distribution within a substrate processing apparatus may be easily visualized.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A substrate processing system comprising:
a substrate processing apparatus including a storage space where a substrate is accommodated;
a camera directed toward the storage space;
a pattern provided to extend within a field of view of the camera and configured to be captured by the camera through the storage space; and
a map generator configured to generate map data indicating a fluid flow distribution in the storage space based on a change of an image of the pattern captured by the camera.

2. The substrate processing system according to claim 1, wherein the map generator generates map data based on a difference between a reference image of the storage space captured by the camera and an evaluation image captured by the camera at a timing when the fluid flow distribution is different from a timing when the reference image is captured.

3. The substrate processing system according to claim 2, wherein the camera has a plurality of pixels, and
the map generator generates the map data based on a difference between a pixel value in the evaluation image and a pixel value in the reference image, for each of the pixels.

4. The substrate processing system according to claim 1, wherein the pattern includes a plurality of motifs arranged to be dispersed in the field of view of the camera.

5. The substrate processing system according to claim 4, wherein the camera has a plurality of pixels, and
an array pitch of the plurality of motifs in the image of the pattern is larger than an array pitch of the plurality of pixels.

6. The substrate processing system according to claim 4, wherein the pattern includes the plurality of motifs that are uniform and are arranged at a constant pitch, and is provided on a surface inclined with respect to a plane perpendicular to an optical axis of the camera.

7. The substrate processing system according to claim 1, wherein the pattern is provided on a partition wall that separates the storage space from a peripheral space.

8. The substrate processing system according to claim 1, further comprising:
a projector provided to extend within the field of view of the camera, and configured to project the pattern onto a surface that is captured by the camera via the storage space.

9. The substrate processing system according to claim 8, wherein the projector projects the pattern onto the surface through a space between the camera and a region of the surface onto which the pattern is projected.

10. The substrate processing system according to claim 8, wherein the camera is fixed to the projector.

11. The substrate processing system according to claim 2, further comprising:
a temperature controller configured to make a temperature of the fluid in the storage space at a timing when the evaluation image is captured to be different from a temperature of the fluid at a timing when the reference image is captured.

12. The substrate processing system according to claim 11, wherein the temperature controller is provided with a thermoelectric element provided in the flow path of the fluid, and configured to supply electric power to the thermoelectric element, thereby changing the temperature of the fluid.

13. The substrate processing system according to claim 2, further comprising:
an additive supply configured to supply an additive that changes a refractive index, to the fluid in the storage space at the timing when the evaluation image is captured.

14. The substrate processing system according to claim 2, wherein the camera repeatedly captures the evaluation image, and
the map generator generates the map data whenever the evaluation image is captured by the camera.

15. The substrate processing system according to claim 14, wherein the map generator updates the reference image based on a plurality of evaluation images obtained by repeatedly capturing the evaluation image with the camera, and generates the map data based on a difference between the updated reference image, and an evaluation image captured after the reference image is updated.

16. The substrate processing system according to claim 1, further comprising:
an expander configured to expand the map data into a series of a plurality of components each of which is expressed by a two-dimensional orthogonal polynomial;
a coefficient modifier configured to modify the coefficient of at least one modification target component among the plurality of components in the series; and
a reconstructor configured to reconstruct the map data based on the series in which the coefficient of the at least one modification target component is modified.

17. The substrate processing system according to claim 16, wherein the two-dimensional orthogonal polynomial is a two-dimensional Legendre polynomial.

18. The substrate processing system according to claim 1, wherein the map generator generates the map data indicating a gas flow distribution as the fluid flow distribution.

19. The substrate processing system according to claim 18, wherein the substrate processing apparatus further includes a liquid supply that supplies a processing liquid to the substrate accommodated in the storage space, and
the map generator generates the map data indicating the gas flow distribution in a state where the processing liquid adheres to the substrate.

20. The substrate processing system according to claim 1, wherein the substrate processing apparatus further includes a second storage space connected to the storage space via an opening, and
the map generator generates the map data indicating the fluid flow distribution around the opening in a state where a temperature of the fluid in the storage space and a temperature of the fluid in the second storage space are different.

21. The substrate processing system according to claim 1, wherein the substrate processing apparatus further includes a gas supply that supplies the processing gas to the substrate accommodated in the storage space, and
the map generator generates the map data indicating the flow distribution of the processing gas, as the fluid flow distribution.

22. A substrate processing apparatus comprising:
a storage space where a substrate is accommodated;
a camera directed toward the storage space; and
a pattern provided to extend within a field of view of the camera, captured by the camera via the storage space, and configured to change the image to be captured by the camera, according to a change in refractive index of the fluid in the storage space.

23. A method of visualizing a fluid flow distribution in a storage space of a substrate processing apparatus where a substrate is accommodated, the method comprising:
acquiring an image of a pattern provided to extend within a field of view of the camera and configure to be captured by a camera through the storage space, the camera being directed toward the storage space; and
generating map data indicating the fluid flow distribution in the storage space based on a change of the image acquired in the acquiring.
